(19) United States
(12) Patent Application Publication
(10) Pub. No.: US 2013/0334608 A1
(43) Pub. Date: Dec. 19, 2013

(54) SEMICONDUCTOR DEVICE

(71) Applicants: Daisaku IKOMA, Aichi (JP); Yoshinao HARADA, Hyogo (JP); Kyouji YAMASHITA, Toyama (JP); Katsuhiro OOTANI, Nara (JP)

(72) Inventors: Daisaku IKOMA, Aichi (JP); Yoshinao HARADA, Hyogo (JP); Kyouji YAMASHITA, Toyama (JP); Katsuhiro OOTANI, Nara (JP)

(21) Appl. No.: 13/942,546

(22) Filed: Jul. 15, 2013

Related U.S. Application Data
(63) Continuation of application No. PCT/JP2011/004152, filed on Jul. 22, 2011.

(30) Foreign Application Priority Data
Feb. 10, 2011 (JP) 2011-026976

(51) Int. Cl. H01L 27/088

(52) U.S. Cl. CPC H01L 27/088
USPC 257/368

(57) ABSTRACT

A semiconductor device includes a first transistor formed on a semiconductor substrate, and including a first channel region, and a first gate electrode formed on the first channel region, and a second transistor formed on the semiconductor substrate, and including a second channel region having a conductivity type identical to a conductivity type of the first channel region, and a second gate electrode formed on the second channel region and having a potential identical to a potential of the first gate electrode. A drain of the first transistor is electrically connected to a source of the second transistor. An absolute value of a threshold voltage of the first transistor is greater than an absolute value of a threshold voltage of the second transistor.

### CROSS-REFERENCE TO RELATED APPLICATIONS

This is a continuation of International Application No. PCT/JP2011/004152 filed on Jul. 22, 2011, which claims priority to Japanese Patent Application No. 2011-026976 filed on Feb. 10, 2011. The entire disclosures of these applications are incorporated by reference herein.

### BACKGROUND

The present disclosure relates to semiconductor devices, and more particularly relates to a semiconductor device including a plurality of metal-insulator-semiconductor field effect transistors (MISFETs) in series.

In order to increase the degrees of integration of semiconductor integrated circuit devices and enhance the function thereof, miniaturization of MISFETs has been actively pursued. As a result, the fabrication cost of a MISFET significantly decreases, and a logic circuit, a memory circuit, or an analog circuit, for example, includes MISFETs; therefore, various functions can be integrated into a single semiconductor integrated circuit device at low cost.

On the other hand, as miniaturization of MISFETs progresses, problems caused by the miniaturization have occurred. For example, in an analog circuit, the drain conductance Gds of each of MISFETs needs to be reduced to achieve the high gain of an amplifier. That is, the output resistance or Early voltage needs to be increased. Incidentally, with decreasing gate length, the drain conductance Gds sharply increases, and the MISFET is consequently degraded; therefore, in an analog circuit, a miniaturized MISFET cannot be used. This prevents a reduction in the chip area (see, e.g., S. Mudanai, et al., “Analytical Modeling of Output Conductance in Long-Channel Halo-Doped MOSFETs,” IEEE Trans. Electron Devices, vol. 53, no. 9, pp. 2091-2097, September 2006).

Furthermore, in a miniaturized MISFET for a logic circuit, in order to reduce short channel effects, diffusion layers are usually introduced below both lateral ends of a channel region, and the diffusion layers have a conductivity type identical to that of the channel region, and a higher impurity concentration than the channel region. The introduction of such diffusion layers is called pocket implantation. The drain conductance Gds is further degraded due to the influence of the pocket implantation, and thus, the performance of an analog circuit using the MISFET for a logic circuit is also degraded.

Typically, in an analog circuit, MISFETs each with a long gate length Lg are used to avoid the influence of degradation in the drain conductance Gds. However, when the gate length of each of devices into which pockets are implanted (hereinafter abbreviated as pocket implantation devices) is long, e.g., 100 nm or longer, the threshold voltage mismatch in the devices (hereinafter referred to as “Vt mismatch”) increases. Therefore, when MISFETs each with a long gate length are simply used, this also causes a problem (see, e.g., United States Patent Publication No. 2008/0116527).

Incidentally, in order to enhance the capability of driving a MISFET made of, in particular, a compound semiconductor, a technique in which the threshold voltage Vt of a MISFET is varied along the gate length of the MISFET, or a technique that allows the gate voltages of transistors in series to be different has been reported (see, e.g., U.S. Pat. No. 5,012,315). The application of the technique has been known to improve the drain conductance Gds.

Examples of factors in determining the drain conductance Gds include channel length modulation, drain induced bather lowering (DIBL), and substrate current resulting from impact ionization. In a usual analog MISFET, while the drain conductance Gds depends also on, e.g., the operating voltage, the DIBL predominantly affects the drain conductance Gds.

A factor in degrading the DIBL is the influence of the high electric field of a portion of a saturation region toward a drain, and in order to reduce the influence, the electric field of a portion thereof toward a source may be increased. In the case of n-type MISFETs, in order to increase the electric field of a portion of a saturation region toward a source, the work function of one of gate electrodes toward the source, or the threshold voltage Vt of one of the n-type MISFETs toward the source may be increased. On the contrary, in the case of p-type MISFETs, the work function of one of gate electrodes toward a source, or the threshold voltage Vt of one of the p-type MISFETs toward the source may be decreased (see, e.g., U.S. Pat. No. 5,012,315).

FIG. 11 illustrates an example of the cross-sectional structure of a MISFET according to a conventional example (see, e.g., S. Mudanai, et al., “Analytical Modeling of Output Conductance in Long-Channel Halo-Doped MOSFETs,” IEEE Trans. Electron Devices, vol. 53, no. 9, pp. 2091-2097, September 2006). The MISFET includes a gate electrode having a portion located toward a source S and having a work function W1, and a portion located toward a drain D and having a work function W2 different from the work function W1. When the MISFET is an n-type MISFET, the work function W1 of the portion of the gate electrode toward the source is increased to increase the threshold voltage Vt of a portion of the MISFET toward the source, thereby reducing the drain conductance Gds.

FIG. 12 illustrates a result of determining the relationship between the electric field of the MISFET illustrated in FIG. 11 along the channel and the gate length by a device simulation. A mechanism for reducing the drain conductance Gds will be described with reference to FIG. 12.

Since, in FIG. 12, the electric field is shown along the vertical axis of the graph, the area of a region of the graph under each of the graph lines represents the potential, and it is assumed that the applied source and drain potentials are fixed. That is, it is assumed that the area is fixed. As described above, the main factor in increasing the drain conductance Gds is DIBL. Thus, a reduction in the influence of the DIBL can improve the drain conductance Gds. A factor in degrading the DIBL is the electric field of a portion of the MISFET toward the drain, and thus, if the electric field of the portion of the MISFET toward the drain can be reduced, this can improve the DIBL, i.e., the drain conductance Gds. In order to reduce the electric field of the portion of the MISFET toward the drain under the condition where the area of the region of the graph under each of the graph lines is fixed, the electric field of a portion of the MISFET toward the source (DMG in the graph) may be increased. To increase the electric field, the resistance of a portion of a channel toward the source may be increased to increase the potential drop of the portion of the channel toward the source. To increase the resistance of the channel, the absolute value |Vt| of the threshold voltage of a portion of the MISFET toward the source may be increased. Alternatively, the work function W1 and the flat band voltage may be changed to correspond to the increase in the absolute value of the threshold voltage.

### SUMMARY

However, it is difficult, in terms of the controllability of the fabrication process, to form a single gate electrode having portions that are located toward the source and the drain and have different work functions or different threshold voltages Vt under the current technical level as described in U.S. Pat. No. 5,012,315. Even if such a gate electrode can be formed, this may cause a plurality of transistors to vary in performance. In the technique described in U.S. Pat. No. 5,012,315, a relatively long gate length Lg is expected to be used, and when pocket implantation devices are used, the Vt mismatch may be worsened.

In another technique described in U.S. Pat. No. 5,012,315, i.e., a method in which a gate electrode is split into two gate electrodes that are portions of transistors in series, and which allows the gate voltages of the split gate electrodes to be different, a circuit configured to generate different gate voltages is separately required, and thus, the chip area increases. Furthermore, in U.S. Pat. No. 5,012,315, the distance between the split gates needs to be approximately equal to the thickness of an insulating film of a MISFET, i.e., the order of several nm, and it is difficult to satisfy the need under the current CMOS microfabrication.

In view of the problems, it is an object of the present disclosure to achieve a semiconductor device configured to reduce the drain conductance Gds of each of a plurality of MISFETs in series by a possible method to improve the performance of an analog circuit while reducing an increase in the chip area and an increase in the fabrication cost. It is another object of the present disclosure to provide a semiconductor device configured to improve the Vt mismatch in addition to the drain conductance Gds when the semiconductor device includes pocket implantation devices.

In order to achieve the object, a semiconductor device according to a first aspect of the present disclosure includes: a first MISFET formed on a semiconductor substrate, and including a first channel region, and a first gate electrode formed on the first channel region; a second MISFET formed on the semiconductor substrate, and including a second channel region having a conductivity type identical to a conductivity type of the first channel region, and a second gate electrode formed on the second channel region and having a potential identical to a potential of the first gate electrode. A drain of the first MISFET is electrically connected to a source of the second MISFET, and an absolute value of a threshold voltage of the first MISFET is greater than an absolute value of a threshold voltage of the second MISFET.

According to the semiconductor device of the first aspect, the absolute value of the threshold voltage of the first MISFET connected toward the source is greater than the absolute value of the threshold voltage of the second MISFET connected toward the drain. Therefore, the electric field of the first MISFET toward the source increases, and thus, satisfactory DIBL characteristics are obtained. As a result, the drain conductance Gds of each of the MISFETs is reduced, thereby improving the performance of an analog circuit while reducing an increase in the chip area and an increase in fabrication cost.

In the semiconductor device of the first aspect, an impurity concentration in the first channel region is preferably higher than an impurity concentration in the second channel region.

In the semiconductor device of the first aspect, the first gate electrode may include a first metal film, the second gate electrode may include a second metal film, and a thickness of the first metal film may be different from a thickness of the second metal film.

In this case, the first and second MISFETs may be p-type MISFETs, the first metal film may have a thickness equal to or less than 15 nm, and the second metal film may have a thickness greater than or equal to 20 nm

Furthermore, in this case, the first and second metal films may be both made of titanium nitride, tantalum nitride, or tantalum carbide.

Preferably, in the semiconductor device of the first aspect, the first gate electrode includes a first silicon film into which impurity atoms have been introduced, the second gate electrode includes a second silicon film into which impurity atoms have been introduced, and a composition of the first silicon film is different from a composition of the second silicon film.

In this case, the first and second MISFETs may be n-type MISFETs, the impurity atoms may be nitrogen atoms, argon atoms, or arsenic atoms, and a concentration of the impurity atoms introduced into the first silicon film may be lower than a concentration of the impurity atoms introduced into the second silicon film.

Furthermore, in this case, the first and second MISFETs may be p-type MISFETs, the impurity atoms may be aluminum atoms, and a concentration of the impurity atoms introduced into the first silicon film may be lower than a concentration of the impurity atoms introduced into the second silicon film.

Preferably, in the semiconductor device of the first aspect, the first MISFET includes a first high-dielectric-constant insulating film formed between the first channel region and the first gate electrode, the second MISFET includes a second high-dielectric-constant insulating film formed between the second channel region and the second gate electrode, and a concentration profile of metal atoms introduced into the first high-dielectric-constant insulating film is different from a concentration profile of metal atoms introduced into the second high-dielectric-constant insulating film.

In this case, the first and second MISFETs may be n-type MISFETs, the metal atoms may be lanthanum atoms, and a concentration of the metal atoms introduced into the first high-dielectric-constant insulating film may be lower than a concentration of the metal atoms introduced into the second high-dielectric-constant insulating film.

Preferably, in the semiconductor device of the first aspect, the first and second MISFETs each have an active region surrounded by an isolation region formed in the semiconductor substrate, and a length of a portion of the first gate electrode of the first MISFET protruding beyond the corresponding active region and extending on the isolation region is different from a length of a portion of the second gate electrode of the second MISFET protruding beyond the corresponding active region and extending on the isolation region.

In this case, the first and second MISFETs may be n-type MISFETs, and the length of the protruding portion of the first gate electrode may be shorter than the length of the protruding portion of the second gate electrode.

Furthermore, in this case, the length of the protruding portion of the first gate electrode may be shorter than 100 nm, and the length of the protruding portion of the second gate electrode may be longer than or equal to 100 nm

A semiconductor device according to a second aspect of the present disclosure includes: a first MISFET formed on a semiconductor substrate, and including an n-type first channel region, and a first gate electrode formed on the first channel region; and a second MISFET formed on the semiconductor substrate, and including an n-type second channel region, and a second gate electrode formed on the second channel region and having a potential identical to a potential of the first gate electrode. A drain of the first MISFET is electrically connected to a source of the second MISFET, and a work function of the first gate electrode is greater than a work function of the second gate electrode.

According to the semiconductor device of the second aspect, in the first and second MISFETs both having a conductivity type that is p-type, the work function of the first gate electrode is greater than that of the second gate electrode. Therefore, the electric field of the first MISFET toward the source increases, and thus, satisfactory DIBL characteristics are obtained. As a result, the drain conductance Gds of each of the MISFETs is reduced, thereby improving the performance of an analog circuit while reducing an increase in the chip area and an increase in fabrication cost.

A semiconductor device according to a third aspect of the present disclosure includes: a first MISFET formed on a semiconductor substrate, and including a p-type first channel region, and a first gate electrode formed on the first channel region; and a second MISFET formed on the semiconductor substrate, and including a p-type second channel region, and a second gate electrode formed on the second channel region and having a potential identical to a potential of the first gate electrode. A drain of the first MISFET is electrically connected to a source of the second MISFET, and a work function of the first gate electrode is less than a work function of the second gate electrode.

According to the semiconductor device of the third aspect, in the first and second MISFETs both having a conductivity type that is n-type, the work function of the first gate electrode is less than that of the second gate electrode. Therefore, the electric field of the first MISFET toward the source increases, and thus, satisfactory DIBL characteristics are obtained. As a result, the drain conductance Gds of each of the MISFETs is reduced, thereby improving the performance of an analog circuit while reducing an increase in the chip area and an increase in fabrication cost.

According to the semiconductor device of the present disclosure, the drain conductance Gds of each of a plurality of MISFETs in series is reduced, thereby improving the performance of an analog circuit. Furthermore, when the semiconductor device includes pocket implantation devices, the Vt mismatch can be also improved.

### BRIEF DESCRIPTION OF THE DRAWINGS

FIG. 1 is a plan view illustrating a semiconductor device according to a first embodiment of the present disclosure.

FIG. 2A is a graph illustrating the dependency of the drain conductance on the gate overdrive of the semiconductor device according to the first embodiment of the present disclosure, which is obtained by a circuit simulation. FIG. 2B is a graph illustrating the dependency of a change in the drain conductance in FIG. 2A on the gate overdrive.

FIG. 3A is a graph illustrating the dependency of the intrinsic gain on the gate overdrive of the semiconductor device according to the first embodiment of the present disclosure, which is obtained by a circuit simulation. FIG. 3B is a graph illustrating the dependency of a change in the intrinsic gain in FIG. 3A on the gate overdrive.

FIG. 4A is a graph illustrating the dependency of the energy efficiency on the gate overdrive of the semiconductor device according to the first embodiment of the present disclosure, which is obtained by a circuit simulation. FIG. 4B is a graph illustrating the dependency of a change in the energy efficiency in FIG. 4A on the gate overdrive.

FIGS. 5A and 5B are cross-sectional views illustrating process steps in a method for fabricating a semiconductor device according to the first embodiment of the present disclosure in sequential order, where an essential portion of the semiconductor device is shown.

FIGS. 6A and 6B are cross-sectional views illustrating other process steps in the method for fabricating a semiconductor device according to the first embodiment of the present disclosure in sequential order, where an essential portion of the semiconductor device is shown.

FIG. 7 is a cross-sectional view illustrating an essential portion of a semiconductor device according to a second embodiment of the present disclosure.

FIG. 8 is a cross-sectional view illustrating an essential portion of a semiconductor device according to a third embodiment of the present disclosure.

FIG. 9 is a cross-sectional view illustrating an essential portion of a semiconductor device according to a fourth embodiment of the present disclosure.

FIG. 10 is a plan view illustrating a semiconductor device according to a fifth embodiment of the present disclosure.

FIG. 11 is a cross-sectional view illustrating a conventional transistor described in S. Mudanai, et al., “Analytical Modeling of Output Conductance in Long-Channel Halo-Doped MOSFETs,” IEEE Trans. Electron Devices, vol. 53, no. 9, pp. 2091-2097, September 2006.

FIG. 12 is a graph illustrating a result of determining the relationship between a location along the channel and the electric field of the conventional transistor described in S. Mudanai, et al., “Analytical Modeling of Output Conductance in Long-Channel Halo-Doped MOSFETs,” IEEE Trans. Electron Devices, vol. 53, no. 9, pp. 2091-2097, September 2006 by a device simulation.

### DETAILED DESCRIPTION

### First Embodiment

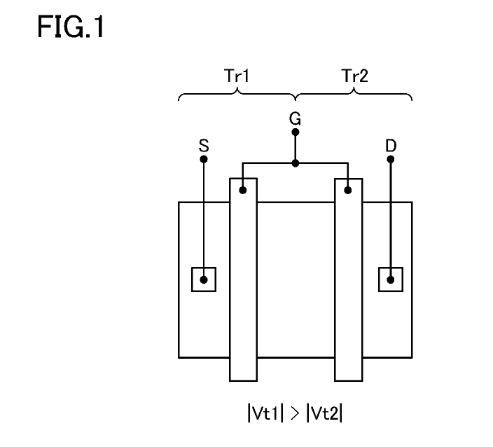

A semiconductor device according to a first embodiment of the present disclosure will be described with reference to FIG. 1.

FIG. 1 illustrates a layout of the semiconductor device including a plurality of MISFETs according to the first embodiment. As illustrated in FIG. 1, the semiconductor device according to the first embodiment includes a first transistor Tr1 and a second transistor Tr2 that are connected in series between a source terminal S and a drain terminal D. Gate electrodes of the first and second transistors Tr1 and Tr2 are connected together, and are at the same potential.

A feature of this embodiment is that the first threshold voltage Vt1 of the first transistor Tr1 is different from the second threshold voltage Vt2 of the second transistor Tr2. For example, when the transistors are n-type MISFETs, the relationship Vt1>Vt2 is satisfied, and when the transistors are p-type MISFETs, the threshold voltages Vt1 and Vt2 are set to satisfy the relationship |Vt1|>|Vt2|.

This configuration can reduce the drain conductance Gds of each of the MISFETs while ensuring ease of fabrication. In this embodiment, the potential of the gate electrode of the first transistor Tr1 is equal to that of the second transistor Tr2. This can reduce the area of a nonessential circuit configured to generate different gate voltages as compared with a situation where different gate potentials are applied to the first and second transistors Tr1 and Tr2. Furthermore, when the transistors are pocket implantation devices, the configuration can make it more difficult to cause the Vt mismatch than a method for causing the threshold voltage Vt of a single gate electrode to vary, resulting in improvement in the analog circuit performance. When the configuration is used in, e.g., a common-source amplifier circuit, the intrinsic gain can be improved, and the performance of a differential amplifier can be improved.

The gate length of the gate electrode of the first transistor Tr1 does not always need to be identical with that of the second transistor Tr2, and the gate lengths may be set at appropriate values with consideration given to the driving forces and analog characteristics of the transistors.

Although, here, a drain of the first transistor Tr1 and a source of the second transistor Tr2 share an impurity diffusion layer, they does not always need to share the impurity diffusion layer, and the drain of the first transistor Tr1 and the source of the second transistor Tr2 may be formed of different impurity diffusion layers, and may be electrically connected together via, e.g., an interconnect.

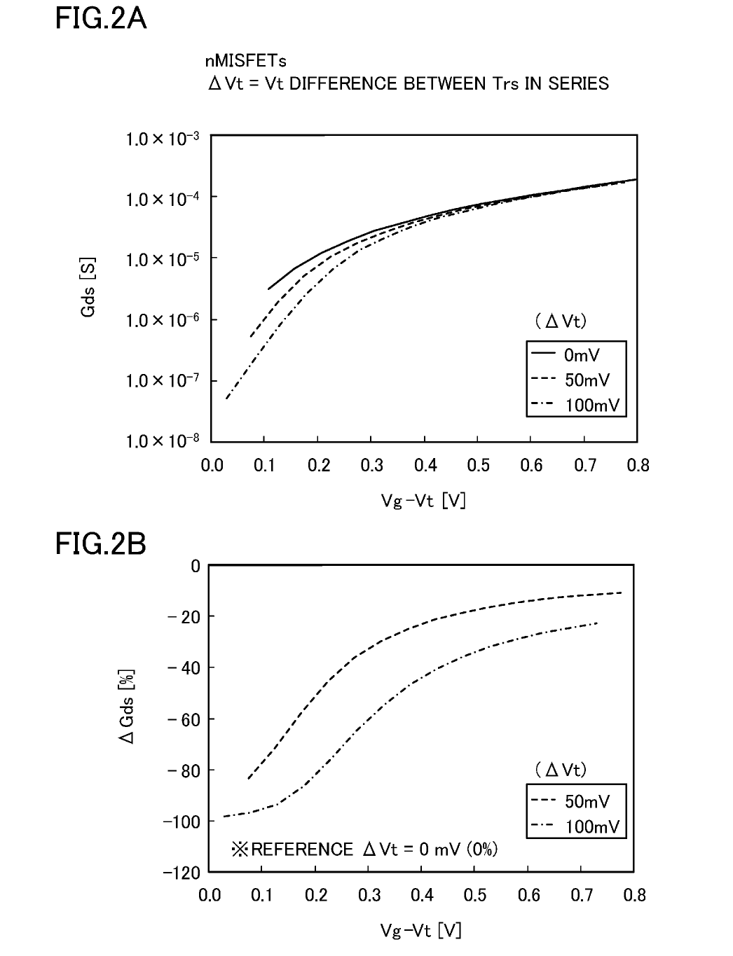

Next, results of quantifying the effect of improving the analog characteristics of the semiconductor device according to the first embodiment by a circuit simulation will be described with reference to FIGS. 2A-4B.

FIG. 2A illustrates the relationship between the drain conductance Gds and the gate overdrive (Vg−Vt). Here, the two transistors Tr1 and Tr2 each having a gate width W of 10 μm and a gate length Lg of 0.2 μm are connected in series. The drain-source voltage Vds is 0.1 V.

The relationship is verified under each of three conditions, i.e., a condition where a difference in threshold voltage Vt (ΔVt) between the first and second transistors Tr1 and Tr2 in series is 0 mV (no difference in threshold voltage Vt), a condition where the difference is 50 mV, and a condition where the difference is 100 mV (where |Vt1|>|Vt2|). The transistor size and the voltage conditions are examples, and similar results can be obtained even with the conditions changed.

The sizes of the first and second transistors Tr1 and Tr2 do not need to be equal to each other. In particular, when the gate lengths Lg of the first and second transistors Tr1 and Tr2 are adjusted, the verification results can be optimized.

FIG. 2B illustrates the rate of decrease ΔGds in drain conductance under each of a condition where the threshold voltage difference ΔVt between n-type MISFETs is 50 mV and a condition where the threshold voltage difference ΔVt is 100 mV, with respect to the drain conductance under a condition where the threshold voltage difference ΔVt is 0 mV.

The simulation results of the drain conductance Gds illustrated in FIGS. 2A and 2B show that increasing the threshold voltage Vt of the first transistor Tr1 toward the source improves (decreases) the drain conductance Gds. In particular, when the gate overdrive (Vg−Vt) is about 0.2 V, which is frequently used in an analog circuit, the drain conductance Gds is improved to an adequate level, and when the threshold voltage difference ΔVt is equal to 100 mV, the drain conductance Gds is reduced by nearly one-half.

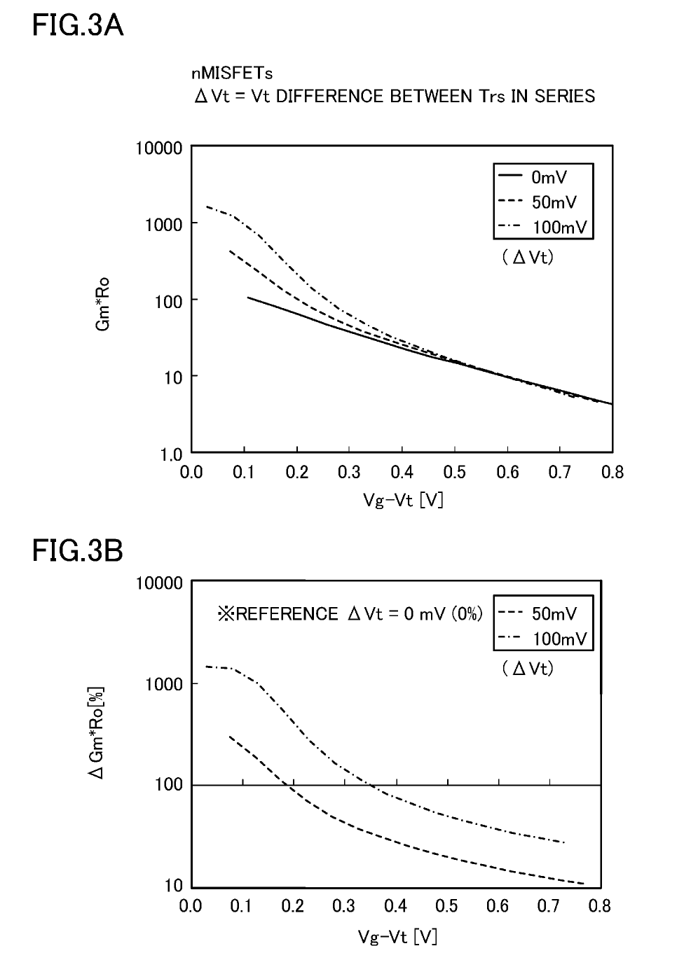

FIG. 3A illustrates simulation results of calculating the intrinsic gain that is the maximum gain specific to a MISFET. The intrinsic gain A can be calculated based on the expression represented by A=Gm/Gds=Gm*Ro, where Gm represents the mutual conductance, and Ro represents the output resistance (=1/Gds).

FIG. 3B illustrates the rate of increase ΔGm*Ro in intrinsic gain under each of a condition where the threshold voltage difference ΔVt between n-type MISFETs is 50 mV and a condition where the threshold voltage difference ΔVt is 100 mV, with respect to the intrinsic gain under a condition where the threshold voltage difference ΔVt is 0 mV.

The simulation results of the intrinsic gain Gm*Ro illustrated in FIGS. 3A and 3B show that increasing the threshold voltage Vt of the first transistor Tr1 toward the source improves the intrinsic gain Gm*Ro. When the threshold voltage difference ΔVt is 100 mV, and the drain overdrive (Vg−Vt) is about 0.2 V, the intrinsic gain Gm*Ro is improved to about three times that when the threshold voltage difference ΔVt is 0 mV.

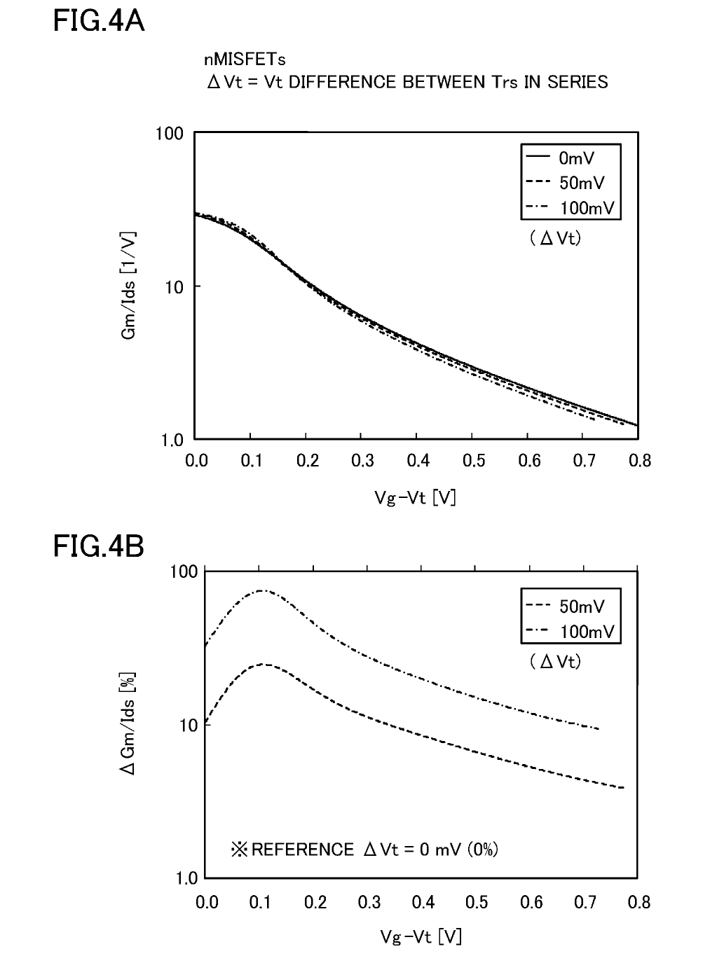

FIGS. 4A and 4B illustrate simulation results of the ratio (Gm/Ids) between the mutual conductance Gm and the drain current Ids, which is an indicator indicating the energy efficiency, for reference purposes. FIGS. 4A and 4B show that the ratio Gm/Ids is also improved in this embodiment.

Next, a method for adjusting the threshold voltages Vt1 and Vt2 of the first and second transistors Tr1 and Tr2 will be described. The method for adjusting the threshold voltages Vt includes various methods.

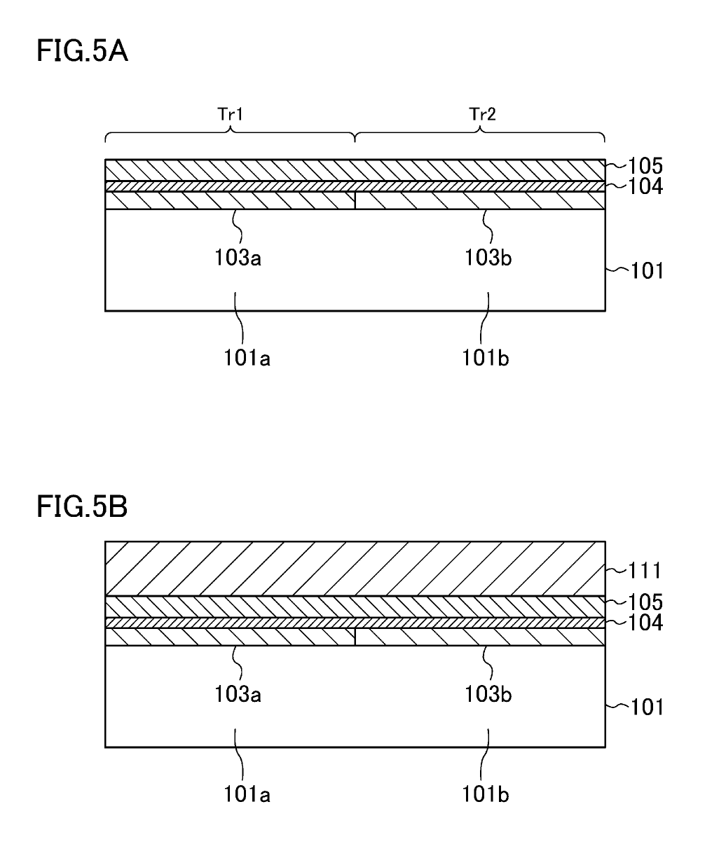

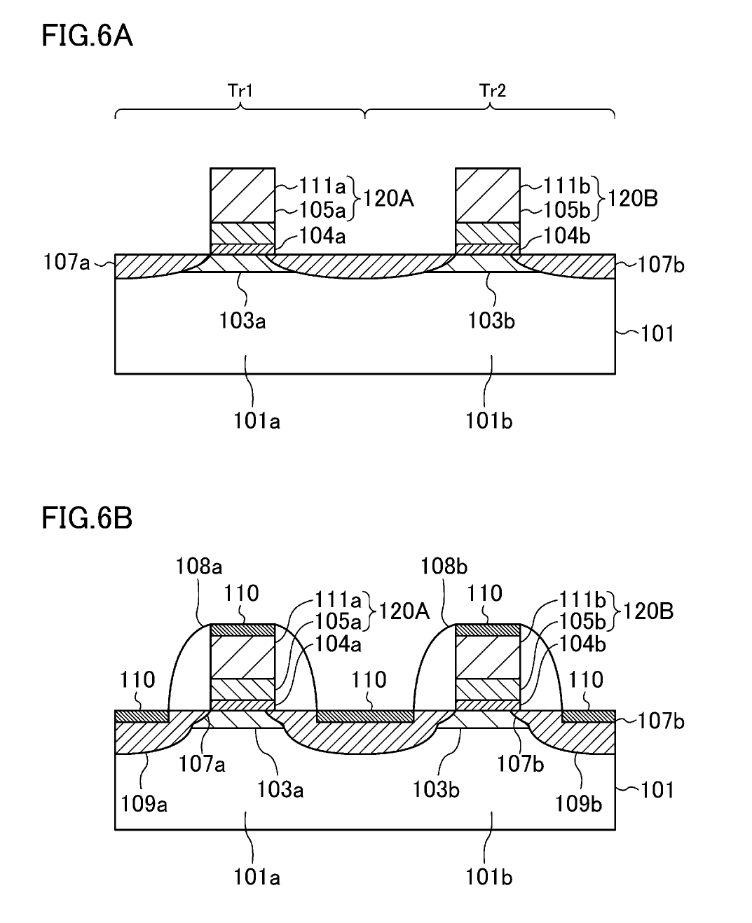

Here, a method in which the threshold voltages Vt are adjusted by impurity implantation will be described with reference to FIGS. 5A-6B together with a method for fabricating a semiconductor device. A semiconductor device including n-type MISFETs will be described, and when the semiconductor device includes p-type MISFETs, the inversion of the polarity of impurities allows the threshold voltages Vt to be adjusted in a manner similar to that when the semiconductor device includes n-type MISFETs.

First, as illustrated in FIG. 5A, a p+ channel region 103a having a first impurity concentration is formed in an upper portion of a semiconductor substrate 101 made of silicon (Si), more specifically, an upper portion of a first active region 101a of the semiconductor substrate 101 forming a portion of a first transistor Tr1, by ion implantation. On the other hand, a p− channel region 103b having a second impurity concentration is formed in an upper portion of a second active region 101b of the semiconductor substrate 101 forming a portion of a second transistor Tr2 by ion implantation, and the second impurity concentration is lower than the first impurity concentration. For example, when boron (B) is used as p-type impurities, the impurity concentration in the p+ channel region 103a is about 2×10¹⁸/cm³, and the impurity concentration in the p− channel region 103b is about 1×10¹⁸/cm³.

Thereafter, a high-dielectric-constant insulating film 104 and a metal film 105 are sequentially formed on the semiconductor substrate 101. Here, for example, titanium nitride (TiN) can be used as a material of the metal film 105.

Next, as illustrated in FIG. 5B, a polysilicon film 111 is formed on the metal film 105.

Next, as illustrated in FIG. 6A, the formed polysilicon film 111, metal film 105, and high-dielectric-constant insulating film 104 are sequentially patterned by etching to form a gate insulating film 104a and a gate electrode 120A of the first transistor Tr1 and a gate insulating film 104b and a gate electrode 120B of the second transistor Tr2. Specifically, the patterning of the high-dielectric-constant insulating film 104 allows the first gate insulating film 104a to be formed on the p+ channel region 103a. Furthermore, the patterning of the metal film 105 and the polysilicon film 111 allows a first metal film 105a and a first polysilicon film 111a to be formed on the first gate insulating film 104a, thereby forming the first gate electrode 120A including the first metal film 105a and the first polysilicon film 111a.

Similarly, the patterning of the high-dielectric-constant insulating film 104 allows the second gate insulating film 104b to be formed on the p− channel region 103b. Furthermore, the patterning of the metal film 105 and the polysilicon film 111 allows a second metal film 105b and a second polysilicon film 111b to be formed on the second gate insulating film 104b, thereby forming the second gate electrode 120B including the second metal film 105b and the second polysilicon film 111b.

Subsequently, n-type impurity ions are implanted into the active regions 101a and 101b using the first and second gate electrodes 120A and 120B as masks, thereby forming shallow n-type source/drain regions 107a and 107b.

Next, as illustrated in FIG. 6B, an insulating film is formed on the semiconductor substrate 101 to cover the first and second gate electrodes 120A and 120B. Subsequently, the formed insulating film is etched back, thereby forming sidewalls 108a made of the insulating film on both side surfaces of the gate electrode 120A, and sidewalls 108b made of the insulating film on both side surfaces of the gate electrode 120B.

Subsequently, n-type impurity ions are implanted into the active regions 101a and 101b using the formed sidewalls 108a and 108b and first and second gate electrodes 120A and 120B as masks, thereby forming deep n-type source/drain regions 109a and 109b.

Thereafter, silicide films 110 are formed in upper portions of the deep n-type source/drain regions 109a and 109b and upper portions of the first and second polysilicon films 111a and 111b of the gate electrodes 120A and 120B.

As described above, in the first embodiment, the impurity concentration in the p+ channel region 103a that is a channel region forming a portion of the first transistor Tr1 is different from that in the p− channel region 103b that is a channel region forming a portion of the second transistor Tr2. Specifically, when the semiconductor device includes n-type MISFETs, the impurity concentration in the channel region of the first transistor Tr1 toward the source terminal is higher than that in the channel region of the second transistor Tr2 toward the drain terminal. This can provide a semiconductor device in which the first threshold voltage Vt1 of the first transistor Tr1 is higher than the second threshold voltage Vt2 of the second transistor Tr2.

As such, according to the first embodiment, the first threshold voltage Vt1 of the first transistor Tr1 connected toward the source is higher than the second threshold voltage Vt2 of the second transistor Tr2 connected toward the drain. Therefore, the electric field of the first transistor Tr1 toward the source increases, and thus, satisfactory DIBL characteristics are obtained. As a result, the drain conductance Gds of the semiconductor device decreases, thereby improving the performance of, e.g., an analog circuit. Furthermore, in the first embodiment, an increase in the chip area of the semiconductor device and an increase in the fabrication cost thereof can be reduced.

Furthermore, when the semiconductor device includes pocket implantation devices, the gate length Lg of each of the devices can be reduced, thereby improving also the Vt mismatch.

In addition to usual implant masks for controlling the threshold voltages Vt, new masks can be used as masks used to implant impurities into corresponding regions to allow the impurity concentrations in the two channel regions illustrated in FIG. 5A to be different; however, the utilization of, e.g., implant masks for an input/output (I/O) circuit eliminates the need for new masks, thereby reducing an increase in the fabrication cost. When a process through which a plurality of threshold voltages (multi-Vt) can be determined is performed, implant masks for multi-Vt may be used.

### Second Embodiment

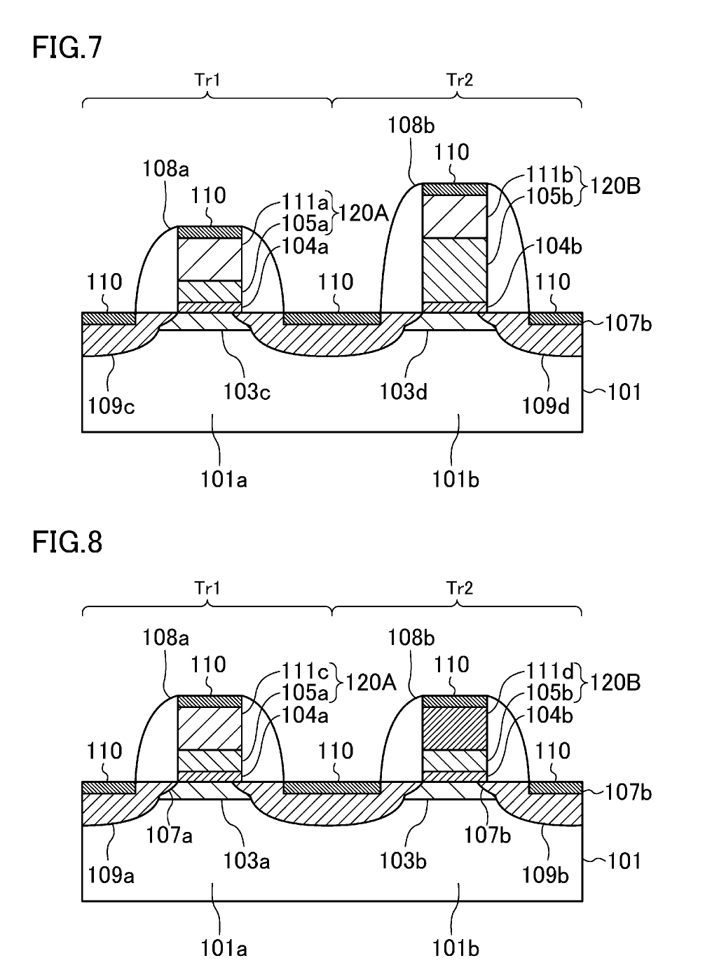

A semiconductor device according to a second embodiment of the present disclosure will be described hereinafter with reference to FIG. 7. In FIG. 7, the same reference characters are used to represent the same components as those in FIG. 6.

FIG. 7 illustrates a semiconductor device including, e.g., p-type MISFETs, a first channel region corresponds to an n-type channel region 103c, and a second channel region corresponds to an n-type channel region 103d. Characters 109c and 109d both denote deep p-type source/drain regions.

As illustrated in FIG. 7, the semiconductor device according to the second embodiment is configured such that the thickness of a first metal film 105a forming a portion of a first gate electrode 120A of a first transistor Tr1 is different from that of a second metal film 105b forming a portion of a second gate electrode 120B of a second transistor Tr2. Thus, in the semiconductor device of this embodiment, the first threshold voltage Vt1 of the first transistor Tr1 and the second threshold voltage Vt2 of the second transistor Tr2 are set at different values.

Assuming that the semiconductor device includes p-type MISFETs using titanium nitride (TiN) as a material of the first and second metal films 105a and 105b, increasing the thickness of the second metal film 105b as illustrated in FIG. 7 increases the work function. Specifically, the Fermi level of the second gate electrode 120B is farther from a mid-gap work function (the intermediate value of band gap energy) and closer to the valence band, and thus, the absolute value of the second threshold voltage Vt2 of the second transistor Tr2 decreases. Therefore, the utilization of this effect allows the threshold voltages Vt1 and Vt2 of the first and second transistors Tr1 and Tr2 to be different.

The thickness of the first metal film 105a is preferably equal to or less than 15 nm, and the thickness of the second metal film 105b is preferably greater than or equal to 20 nm

The material of the metal films 105a and 105b is not limited to titanium nitride (TiN), and tantalum nitride (TaN) or tantalum carbide (TaC) can be used as the material.

In the second embodiment, unlike the first embodiment, no difference needs to be made between the threshold voltage Vt1 of the first transistor Tr1 and the threshold voltage Vt2 of the second transistor Tr2 by the difference in ion implantation for Vt control between the first and second transistors Tr1 and Tr2, and thus, the impurity concentration in the n-type channel region 103c may be equal to the impurity concentration in the n-type channel region 103d.

### Third Embodiment

A semiconductor device according to a third embodiment of the present disclosure will be described hereinafter with reference to FIG. 8. In FIG. 8, the same reference characters are used to represent the same components as those in FIG. 6.

As illustrated in FIG. 8, the semiconductor device according to the third embodiment is configured such that the condition on which a first polysilicon film 111c forming a portion of a first gate electrode 120A of a first transistor Tr1 is formed, i.e., the composition of the first polysilicon film 111c, is different from the condition on which a second polysilicon film 111d forming a portion of a second gate electrode 120B of a second transistor Tr2 is formed, i.e., the composition of the second polysilicon film 111d. Thus, the threshold voltages Vt1 and Vt2 of the first and second transistors Tr1 and Tr2 are set at different values.

Specifically, in the step illustrated in FIG. 5B, i.e., the step of forming the polysilicon film 111, impurities of, e.g., nitrogen (N), argon (Ar), aluminum (Al), or arsenic (As) are introduced into the polysilicon film 111 to allow the work function of the first transistor Tr1 to be different from that of the second transistor Tr2, thereby causing a difference in threshold voltage Vt between the first and second transistors Tr1 and Tr2.

More specifically, when the semiconductor device includes n-type MISFETs, the second threshold voltage Vt2 of the second transistor Tr2 can be reduced by introducing nitrogen (N), argon (Ar), or arsenic (As) into a region of the polysilicon film 111 forming a portion of the second transistor Tr2 by, e.g., ion implantation.

In this case, the amount (dose) of implanted N, Ar, or As is preferably greater than or equal to 1×10¹⁶ cm⁻².

Alternatively, when aluminum (Al) ions are implanted into the polysilicon film 111, this can reduce the threshold voltage Vt of a p-type MISFET, and can increase the threshold voltage Vt of an n-type MISFET. That is, the implantation of Al ions can increase the absolute value of the threshold voltage Vt of a p-type MISFET and the absolute value of the threshold voltage Vt of an n-type MISFET. Therefore, aluminum (Al) may be introduced into the first polysilicon film 111c forming a portion of the first transistor Tr1. In this case, the amount (dose) of implanted Al is preferably greater than or equal to 1×10¹⁵ cm ².

Also in the third embodiment, unlike the first embodiment, no difference needs to be made between the threshold voltage Vt1 of the first transistor Tr1 and the threshold voltage Vt2 of the second transistor Tr2 by the difference in ion implantation for Vt control between the first and second transistors Tr1 and Tr2, and thus, the impurity concentration in the p-type channel region 103a may be equal to the impurity concentration in the p-type channel region 103b.

### Fourth Embodiment

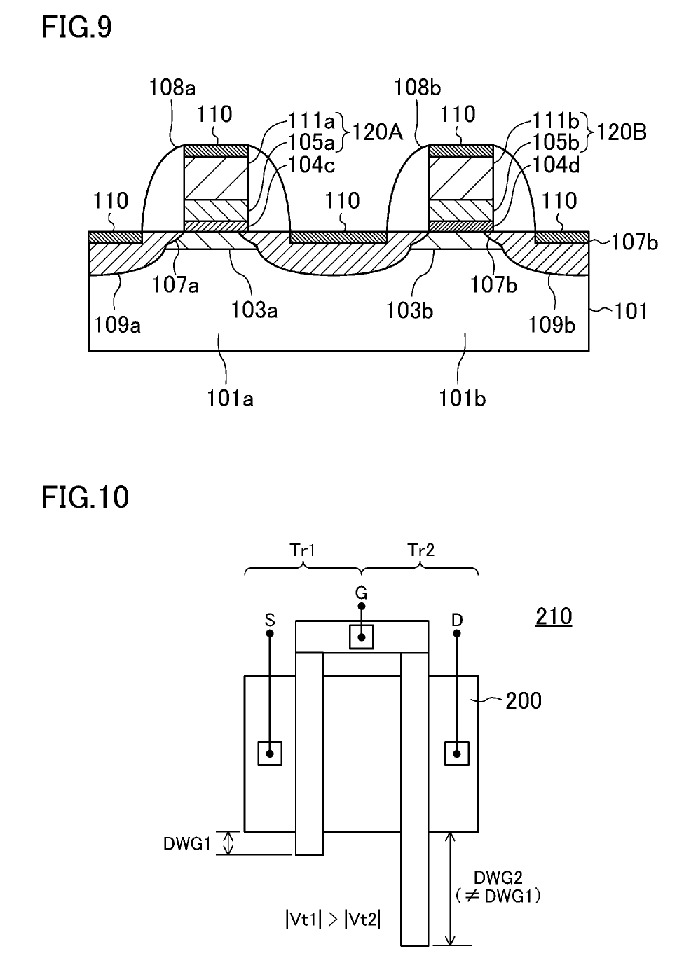

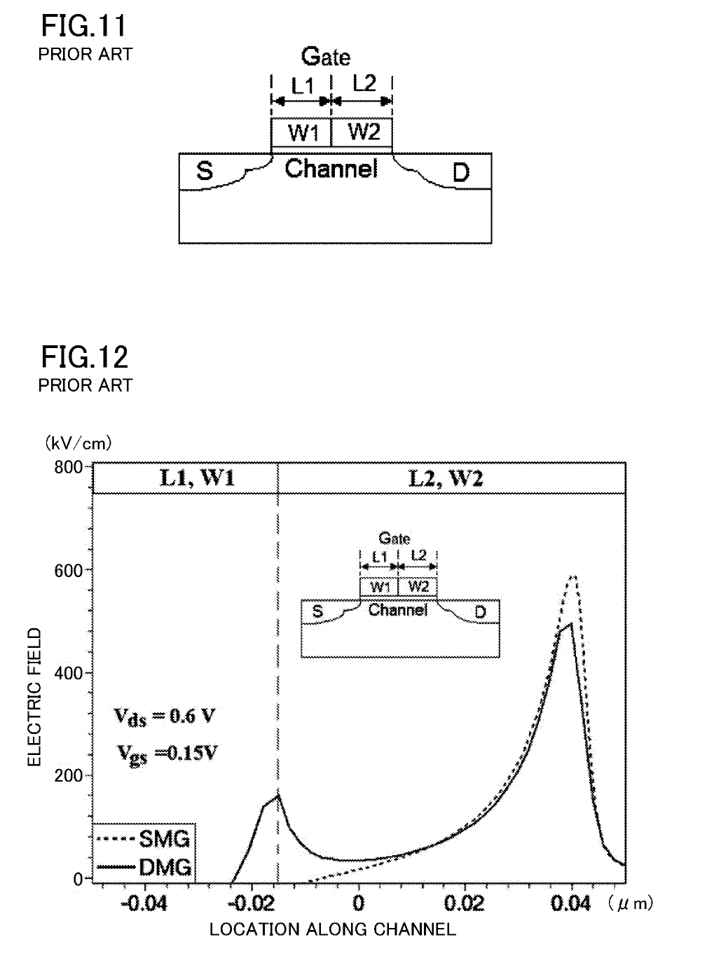

A semiconductor device according to a fourth embodiment of the present disclosure will be described hereinafter with reference to FIG. 9. In FIG. 9, the same reference characters are used to represent the same components as those in FIG. 6.

As illustrated in FIG. 9, the semiconductor device according to the fourth embodiment is configured such that the condition on which a first gate insulating film 104c under a first gate electrode 120A of a first transistor Tr1 is formed, i.e., the composition of the first gate insulating film 104c, is different from the condition on which a second gate insulating film 104d under a second gate electrode 120B of a second transistor Tr2, i.e., the composition of the second gate insulating film 104d. Thus, the threshold voltages Vt1 and Vt2 of the first and second transistors Tr1 and Tr2 are set at different values.

Specifically, when the semiconductor device includes n-type MISFETs, lanthanum (La) is introduced into the high-dielectric-constant insulating film 104 containing hafnium (Hf) oxide in the step illustrated in FIG. 5A, i.e., the step of forming the high-dielectric-constant insulating film 104, and in the introduction of lanthanum, the amount of La introduced into the first transistor Tr1 and the amount of La introduced into the second transistor Tr2 are different.

Alternatively, lanthanum may be introduced into the high-dielectric-constant insulating film 104 such that the high-dielectric-constant insulating film 104 has a uniform La concentration, and in a heat treatment step, a reflective film may be deposited over a region of the substrate corresponding to any one of the first and second transistors Tr1 and Tr2. Thus, the effective heat treatment temperature for a region of the high-dielectric-constant insulating film 104 covered with the reflective film decreases, thereby allowing the profile of the lanthanum concentration in the first gate insulating film 104c to be different from that in the second gate insulating film 104d. As a result, the work function of the first transistor Tr1 is different from that of the second transistor Tr2, resulting in a difference between the threshold voltages Vt1 and Vt2 of the first and second transistors Tr1 and Tr2.

For example, in order to allow the value |Vt1| to be greater than the value |Vt2|, the lanthanum concentration in the first gate insulating film 104c is lower than that in the second gate insulating film 104d.

For example, an aluminum (Al) film can be utilized as the reflective film.

The metal that can be introduced into the gate insulating films, i.e., portions of the high-dielectric-constant insulating film, is not limited to lanthanum (La), and a rare earth element, such as scandium (Sc) or dysprosium (Dy), can be used as the metal.

Also in the fourth embodiment, unlike the first embodiment, no difference needs to be made between the threshold voltage Vt1 of the first transistor Tr1 and the threshold voltage Vt2 of the second transistor Tr2 by the difference in ion implantation for Vt control between the first and second transistors Tr1 and Tr2, and thus, the impurity concentration in the p-type channel region 103a may be equal to the impurity concentration in the p-type channel region 103b.

### Fifth Embodiment

A semiconductor device according to a fifth embodiment of the present disclosure will be described hereinafter with reference to FIG. 10.

As illustrated in FIG. 10, the semiconductor device according to the fifth embodiment is configured such that the lengths of gate electrodes of first and second transistors Tr1 and Tr2 having the same gate potential and connected in series are different.

Specifically, portions of the gate electrodes protruding beyond a diffusion region 200 that is an active region and extending on an isolation region 210 surrounding the diffusion region 200 have different lengths, i.e., different gate protrusion lengths DWG1 and DWG2, thereby providing a semiconductor device in which the first threshold voltage Vt1 of the first transistor Tr1 is different from the second threshold voltage Vt2 of the second transistor Tr2.

Incidentally, when a semiconductor device including high-k metal gate MISFETs that use a high-dielectric-constant insulating film and metal as a gate insulating film and a gate electrode, respectively, is fabricated by a so-called gate-first process in which gate electrodes are formed before the formation of source/drain regions, the following phenomenon has been known to occur.

Specifically, the phenomenon is that from the isolation region 210 made of an insulating film of, e.g., silicon dioxide (SiO₂), oxygen in the insulating film is diffused into the gate insulating film depending on the gate protrusion lengths, thereby allowing the threshold voltages Vt of the transistors to be different. Here, with decreasing gate protrusion length, the threshold voltage Vt of the corresponding transistor increases.

Thus, when the first transistor Tr1 having a short gate protrusion length is placed toward a source, a difference is made between the threshold voltages Vt of the first and second transistors Tr1 and Tr2, and as a result, the drain conductance Gds can be improved.

Even when the semiconductor device does not include high-k metal gate MISFETs, the magnitudes of stresses applied from stress films formed on gate electrodes to transistors Tr1 and Tr2 are made different by allowing the set gate protrusion lengths to be different, and the utilization of the stress variations can cause a difference between the threshold voltages Vt of the transistors.

For example, when the first and second transistors Tr1 and Tr2 are n-type MISFETs in each of which lanthanum (La) has been diffused into a gate insulating film made of a high-dielectric-constant insulator, a difference of about 50 mV can be made between the threshold voltages Vt of the transistors by setting the gate protrusion length DWG1 of the first transistor Tr1 at 50 nm, and setting the gate protrusion length DWG2 of the second transistor Tr2 at 200 nm Specifically, the first threshold voltage Vt1 of the first transistor Tr1 can be about 50 mV higher than the second threshold voltage Vt2 of the second transistor Tr2.

Preferably, the gate protrusion length DWG1 of the first transistor Tr1 is shorter than 100 nm, and the gate protrusion length DWG2 of the second transistor Tr2 is longer than or equal to 100 nm.

Also in the fifth embodiment, unlike the first embodiment, no difference needs to be made between the threshold voltage Vt1 of the first transistor Tr1 and the threshold voltage Vt2 of the second transistor Tr2 by the difference in ion implantation for Vt control between the first and second transistors Tr1 and Tr2, and thus, the impurity concentrations in unshown channel regions may be equal to each other.

A semiconductor device according to the present disclosure can reduce the drain conductance Gds of each of a plurality of MISFETs in series to improve the performance of an analog circuit, and can further improve the Vt mismatch when the semiconductor device includes pocket implantation devices. The semiconductor device is useful, in particular, for, e.g., semiconductor devices including a high-performance analog circuit.

What is claimed is:

1. A semiconductor device comprising:
a first MISFET formed on a semiconductor substrate, and including a first channel region, and a first gate electrode formed on the first channel region;
a second MISFET formed on the semiconductor substrate, and including a second channel region having a conductivity type identical to a conductivity type of the first channel region, and a second gate electrode formed on the second channel region and having a potential identical to a potential of the first gate electrode, wherein
a drain of the first MISFET is electrically connected to a source of the second MISFET, and
an absolute value of a threshold voltage of the first MISFET is greater than an absolute value of a threshold voltage of the second MISFET.

2. The semiconductor device of claim 1, wherein
an impurity concentration in the first channel region is higher than an impurity concentration in the second channel region.

3. The semiconductor device of claim 1, wherein
the first gate electrode includes a first metal film,
the second gate electrode includes a second metal film, and
a thickness of the first metal film is different from a thickness of the second metal film.

4. The semiconductor device of claim 3, wherein
the first and second MISFETs are p-type MISFETs,
the first metal film has a thickness equal to or less than 15 nm, and
the second metal film has a thickness greater than or equal to 20 nm

5. The semiconductor device of claim 4, wherein
the first and second metal films are both made of titanium nitride, tantalum nitride, or tantalum carbide.

6. The semiconductor device of claim 1, wherein
the first gate electrode includes a first silicon film into which impurity atoms have been introduced,
the second gate electrode includes a second silicon film into which impurity atoms have been introduced, and
a composition of the first silicon film is different from a composition of the second silicon film.

7. The semiconductor device of claim 6, wherein
the first and second MISFETs are n-type MISFETs,
the impurity atoms are nitrogen atoms, argon atoms, or arsenic atoms, and
a concentration of the impurity atoms introduced into the first silicon film is lower than a concentration of the impurity atoms introduced into the second silicon film.

8. The semiconductor device of claim 6, wherein
the first and second MISFETs are p-type MISFETs,
the impurity atoms are aluminum atoms, and
a concentration of the impurity atoms introduced into the first silicon film is lower than a concentration of the impurity atoms introduced into the second silicon film.

9. The semiconductor device of claim 1, wherein
the first MISFET includes a first high-dielectric-constant insulating film formed between the first channel region and the first gate electrode,
the second MISFET includes a second high-dielectric-constant insulating film formed between the second channel region and the second gate electrode, and
a concentration profile of metal atoms introduced into the first high-dielectric-constant insulating film is different from a concentration profile of metal atoms introduced into the second high-dielectric-constant insulating film.

10. The semiconductor device of claim 9, wherein
the first and second MISFETs are n-type MISFETs,
the metal atoms are lanthanum atoms, and
a concentration of the metal atoms introduced into the first high-dielectric-constant insulating film is lower than a concentration of the metal atoms introduced into the second high-dielectric-constant insulating film.

11. The semiconductor device of claim 1, wherein
the first and second MISFETs each have an active region surrounded by an isolation region formed in the semiconductor substrate, and
a length of a portion of the first gate electrode of the first MISFET protruding beyond the corresponding active region and extending on the isolation region is different from a length of a portion of the second gate electrode of the second MISFET protruding beyond the corresponding active region and extending on the isolation region.

12. The semiconductor device of claim 11, wherein
the first and second MISFETs are n-type MISFETs, and
the length of the protruding portion of the first gate electrode is shorter than the length of the protruding portion of the second gate electrode.

13. The semiconductor device of claim 12, wherein
the length of the protruding portion of the first gate electrode is shorter than 100 nm, and
the length of the protruding portion of the second gate electrode is longer than or equal to 100 nm

14. A semiconductor device comprising:
a first MISFET formed on a semiconductor substrate, and including an n-type first channel region, and a first gate electrode formed on the first channel region; and
a second MISFET formed on the semiconductor substrate, and including an n-type second channel region, and a second gate electrode formed on the second channel region and having a potential identical to a potential of the first gate electrode, wherein
a drain of the first MISFET is electrically connected to a source of the second MISFET, and
a work function of the first gate electrode is greater than a work function of the second gate electrode.

15. A semiconductor device comprising:
a first MISFET formed on a semiconductor substrate, and including a p-type first channel region, and a first gate electrode formed on the first channel region; and
a second MISFET formed on the semiconductor substrate, and including a p-type second channel region, and a second gate electrode formed on the second channel region and having a potential identical to a potential of the first gate electrode, wherein
a drain of the first MISFET is electrically connected to a source of the second MISFET, and
a work function of the first gate electrode is less than a work function of the second gate electrode.
